(19) United States
(12) Patent Application Publication
(10) Pub. No.: US 2004/0245609 A1
(43) Pub. Date: Dec. 9, 2004

(54) Package structure for an integrated circuit

(76) Inventor: Potter Chien, Hsinchu Hsien (TW)

Correspondence Address: PRO-TECHTOR INTERNATIONAL, 20775 Norada Court, Saratoga, CA, 95070-3018, US

(21) Appl. No.: 10/454,647

(22) Filed: Jun. 3, 2003

(51) Int. Cl. H01L 23/02; H01L 23/04

(52) U.S. Cl. 257/678

(57) ABSTRACT

A package structure includes a substrate, a spacer layer, an integrated circuit, a plurality of wires, and a glue layer. The substrate has an upper surface formed with first connection points, and a lower surface formed with second connection points. The spacer layer is adhered to the upper surface of the substrate by a first adhesive. The integrated circuit has a plurality of bonding pads and is adhered to the spacer layer by a second adhesive. The integrated circuit has an area larger than that of the spacer layer such that a gap is formed between the integrated circuit and the substrate. The wires electrically connect the bonding pads of the integrated circuit to the first connection points of the substrate, respectively. The glue layer is formed on the upper surface of the substrate to encapsulate the integrated circuit and the wires.

### BACKGROUND OF THE INVENTION

1. Field of the Invention

The invention relates to a package structure for an integrated circuit, and more particularly to a package structure for an integrated circuit with increased throughput.

2. Description of the Related Art

Referring to FIG. 1, a conventional package structure of an integrated circuit includes a substrate 10, an integrated circuit 20, a plurality of wires 26, and a glue layer 28. The substrate 10 has an upper surface 12 formed with a plurality of first connection points 16, and a lower surface 14 formed with a plurality of second connection points 18. The integrated circuit 20 is formed with a plurality of bonding pads 22, and is adhered to the upper surface 12 of the substrate 10 by an adhesive 24. The wires 26 electrically connect the bonding pads 22 of the integrated circuit 20 to the first connection points 16 of the substrate 10, respectively. The glue layer 28 is formed on the upper surface 12 of the substrate 10 to encapsulate the integrated circuit 20 and the wires 26.

However, the above-mentioned package structure has the following drawbacks. Since the integrated circuit 20 is adhered to the upper surface 12 of the substrate 10 by the adhesive 24, the overflowing adhesive 24 may cover the first connection points 16 of the substrate 10 if the adhesive is not well controlled. In this case, the wires 26 may not be bonded to the substrate 10 or the bonded wires 26 may tend to fall down.

### SUMMARY OF THE INVENTION

An object of the invention is to provide a package structure for an integrated circuit capable of facilitating the wire bonding process and increasing the throughput.

To achieve the above-mentioned object, the invention provides a package structure includes a substrate, a spacer layer, an integrated circuit, a plurality of wires, and a glue layer. The substrate has an upper surface formed with a plurality of first connection points, and a lower surface formed with a plurality of second connection points. The spacer layer is adhered to the upper surface of the substrate by a first adhesive. The integrated circuit has a plurality of bonding pads and is adhered to the spacer layer by a second adhesive. The integrated circuit has an area larger than that of the spacer layer such that a gap is formed between the integrated circuit and the substrate. The wires electrically connect the bonding pads of the integrated circuit to the first connection points of the substrate, respectively. The glue layer is formed on the upper surface of the substrate to encapsulate the integrated circuit and the wires.

Therefore, the overflowing adhesive cannot contaminate the first connection points, the wire bonding process is convenient, and the throughput may be improved.

### BRIEF DESCRIPTION OF THE DRAWINGS

FIG. 1 is a schematic illustration showing a conventional package structure for an integrated circuit.

FIG. 2 is a first schematic illustration showing a package structure for an integrated circuit of the invention.

FIG. 3 is a second schematic illustration showing the package structure for the integrated circuit of the invention.

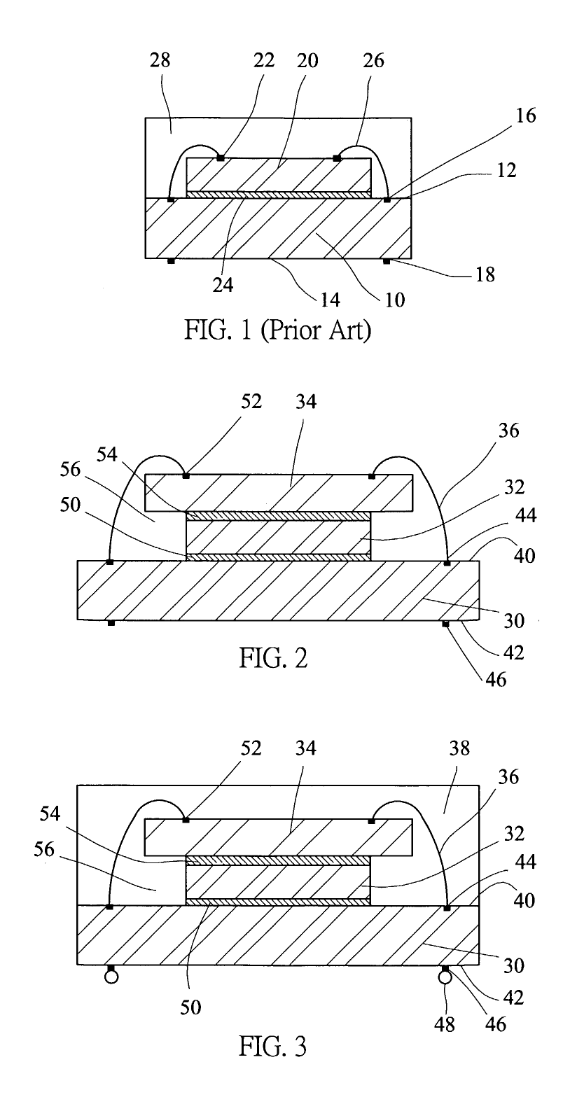

### DETAILED DESCRIPTION OF THE INVENTION

Referring to FIGS. 2 and 3, a package structure for an integrated circuit of the invention includes a substrate 30, a spacer layer 32, an integrated circuit 34, a plurality of wires 36, and a glue layer 38.

The substrate 30 has an upper surface 40 formed with a plurality of first connection points 44, and a lower surface 42 formed with a plurality of second connection points 46. The second connection points 46 are formed with BGA (Ball Grid Array) metallic balls 48.

The spacer layer 32 is adhered to the upper surface 40 of the substrate 30 by a first adhesive 50.

The integrated circuit 34 has a plurality of bonding pads 52 and is adhered to the spacer layer 32 by a second adhesive 54. The area of the integrated circuit 34 is larger than that of the spacer layer 32 such that a gap 56 is defined between the integrated circuit 34 and the substrate 30.

The wires 36 electrically connect the bonding pads 52 of the integrated circuit 34 to the first connection points 44 of the substrate 30, respectively. Thus, the signals from the integrated circuit 34 may be transferred to the substrate 30.

The glue layer 38 is formed on the upper surface 40 of the substrate 30 to encapsulate the integrated circuit 34 and the wires 36.

The package structure of the invention has the following advantages. Since the integrated circuit 34 is adhered to the spacer layer 32 that is adhered to the substrate 30, the gap 56 can be defined between the integrated circuit 34 and the substrate 30. Thus, the overflowing first adhesive 50 may cannot cover the first connection points 44, the wire bonding process is convenient, and the throughput may be increased.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A package structure, comprising:
a substrate having an upper surface formed with a plurality of first connection points, and a lower surface formed with a plurality of second connection points;
a spacer layer adhered to the upper surface of the substrate by a first adhesive;
an integrated circuit having a plurality of bonding pads and being adhered to the spacer layer by a second adhesive, the integrated circuit having an area larger than that of the spacer layer such that a gap is formed between the integrated circuit and the substrate;
a plurality of wires for electrically connecting the bonding pads of the integrated circuit to the first connection points of the substrate, respectively; and
a glue layer formed on the upper surface of the substrate to encapsulate the integrated circuit and the wires.

2. The package structure according to claim 1, wherein the second connection points on the lower surface of the substrate are formed with BGA (Ball Grid Array) metallic balls.
